(19) United States
(12) Patent Application Publication
(10) Pub. No.: US 2026/0018197 A1
(43) Pub. Date: Jan. 15, 2026

(54) SENSE AMPLIFIER, VOLTAGE CONTROL METHOD, AND MEMORY

(71) Applicant: Wuhan Xinxin Semiconductor Manufacturing Co., Ltd., Wuhan (CN)

(72) Inventor: Qiaohong CUI, Wuhan (CN)

(73) Assignee: Wuhan Xinxin Semiconductor Manufacturing Co., Ltd., Wuhan (CN)

(21) Appl. No.: 19/255,665

(22) Filed: Jun. 30, 2025

(30) Foreign Application Priority Data
Jul. 11, 2024 (CN) 202410930006.2

(51) Int. Cl. G11C 7/12; G11C 7/08; G11C 7/22

(52) U.S. Cl. CPC G11C 7/12; G11C 7/08; G11C 7/222

(57) ABSTRACT

The application discloses a sense amplifier, a voltage control method, and a memory. The sense amplifier includes a first transistor, a second transistor, and a voltage regulator, wherein through the voltage regulator, based on an enable signal and a potential of a bit line, a potential of a first node is pulled down, allowing the potential of the first node to be pulled down during a precharge phase, and further enabling the potential of the bit line to be reduced through the first transistor, thereby alleviating the technical problem of the bit line potential being excessively high during the precharge phase of a read operation.

### CROSS REFERENCE TO RELATED APPLICATIONS

The present application claims the priority to Chinese Patent Application No. 202410930006.2 filed on Jul. 11, 2024. The entire disclosures of the above application are incorporated herein by reference.

### FIELD OF INVENTION

The present application relates to the field of memory technology, specifically to a sense amplifier, a voltage control method, and a memory.

### BACKGROUND OF INVENTION

Due to the structural reasons of the memory array in a memory, the distances from memory cells to the sense amplifier via bit lines are different. The bit line connected to a memory cell close to the sense amplifier is shorter, so the load on the bit line is lighter, easily causing the potential of the bit line to be excessively high.

If the potential of the bit line is excessively high, during the amplification output phase, the sense amplifier has not reached a stable state for quick response, and under the influence of power supply noise, read errors are prone to occur.

### SUMMARY OF INVENTION

The present application provides a sense amplifier, a voltage control method, and a memory to alleviate the technical problem of the bit line potential being excessively high during the precharge phase of a read operation.

In a first aspect, the present application provides a sense amplifier, the sense amplifier includes a first transistor, a second transistor, and a voltage regulator, wherein the first transistor configured to control a connection between a second node and a bit line based on a potential of a first node; wherein the second transistor is configured to pull down the potential of the first node based on the potential of the bit line; wherein the voltage regulator is configured to pull down the potential of the first node based on an enable signal and the potential of the bit line.

In some embodiments, the voltage regulator includes a pull-down time controller and a pull-down controller, the pull-down time controller is configured to control a pull-down time of the potential of the first node based on the enable signal; the pull-down controller is configured to conduct a connection between the first node and the pull-down time controller when the potential of the bit line is greater than a preset potential.

In some embodiments, the pull-down controller includes a third transistor, a first terminal of the third transistor is connected to the first node, a control terminal of the third transistor is connected to the bit line, and a second terminal of the third transistor is connected to the pull-down time controller.

In some embodiments, the third transistor is an N-channel transistor, and the preset potential is a sum of a threshold voltage of the third transistor and a source potential of the third transistor.

In some embodiments, the pull-down time controller includes a fourth transistor, a first terminal of the fourth transistor is connected to the second terminal of the third transistor, a control terminal of the fourth transistor is connected to the enable signal, and a second terminal of the fourth transistor is connected to a ground terminal.

In some embodiments, the voltage regulator includes a pull-down time controller and a pull-down controller, the pull-down time controller is configured to control a pull-down time of the potential of the first node based on the enable signal; the pull-down controller is configured to conduct a connection between the pull-down time controller and a ground terminal when the potential of the bit line is greater than a preset potential.

In some embodiments, the pull-down controller includes a third transistor, a first terminal of the third transistor is connected to the pull-down time controller, a control terminal of the third transistor is connected to the bit line, and a second terminal of the third transistor is connected to the ground terminal.

In some embodiments, the pull-down time controller includes a fourth transistor, a first terminal of the fourth transistor is connected to the first node, a control terminal of the fourth transistor is connected to the enable signal, and a second terminal of the fourth transistor is connected to the first terminal of the third transistor.

In some embodiments, the sense amplifier further includes a fifth transistor, a sixth transistor, and a seventh transistor, a first terminal of the fifth transistor is connected to a power supply terminal, a control terminal of the fifth transistor is connected to a control terminal of the voltage regulator to receive the enable signal; a first terminal of the sixth transistor is connected to a second terminal of the fifth transistor, a control terminal of the sixth transistor is connected to the second node; a first terminal of the seventh transistor is connected to a second terminal of the sixth transistor and outputs a corresponding readout signal, a control terminal of the seventh transistor is connected to a first bias signal, and a second terminal of the seventh transistor is connected to a ground terminal.

In some embodiments, the sense amplifier further includes a tenth transistor, an eleventh transistor, and a twelfth transistor, a first terminal of the tenth transistor is connected to a power supply terminal, a control terminal of the tenth transistor is connected to a precharge control signal, and a second terminal of the tenth transistor is connected to the second node; a first terminal of the eleventh transistor is connected to the power supply terminal, and a control terminal of the eleventh transistor is connected to a ground terminal; a first terminal of the twelfth transistor is connected to a second terminal of the eleventh transistor, a control terminal of the twelfth transistor is connected to a third bias signal, and a second terminal of the twelfth transistor is connected to the second node.

In some embodiments, the enable signal is enabled for a time period when the potential of the bit line begins to change.

In a second aspect, the present application provides a voltage control method, the voltage control method is applied to the above-mentioned sense amplifier, and the voltage control method comprises: controlling a connection between a second node and a bit line based on a potential of a first node; pulling down the potential of the first node based on the potential of the bit line; pulling down the potential of the first node based on an enable signal and the potential of the bit line.

In some embodiments, the step of pulling down the potential of the first node based on the enable signal and the potential of the bit line comprises: enabling the enable signal for a time period when the potential of the bit line begins to change.

In some embodiments, the step of enabling the enable signal for a time period when the potential of the bit line begins to change comprises: pulling down the potential of the first node based on the enable signal and the potential of the bit line during a first time period when the potential of the bit line begins to change; and stopping the pulling down of the potential of the first node based on the enable signal during a second time period following the first time period.

In a third aspect, the present application provides a memory, the memory comprises the above-mentioned sense amplifier.

The sense amplifier, voltage control method, and memory provided by the present application, through the voltage regulator pulling down the potential of the first node based on the enable signal and the potential of the bit line, can pull down the potential of the first node during the precharge phase, and further enable the potential of the bit line to be reduced through the first transistor, thereby alleviating the technical problem of the bit line potential being excessively high during the precharge phase of a read operation.

### DESCRIPTION OF DRAWINGS

The technical solutions and other beneficial effects of the present application will become apparent through a detailed description of the specific embodiments of the present application in conjunction with the accompanying drawings below.

FIG. 1 is a principle block diagram of a sense amplifier provided by an embodiment of the present application.

FIG. 2 is a first principle block diagram of a voltage regulator provided by an embodiment of the present application.

FIG. 3 is a first circuit principle diagram of a voltage regulator provided by an embodiment of the present application.

FIG. 4 is a second principle block diagram of a voltage regulator provided by an embodiment of the present application.

FIG. 5 is a second circuit principle diagram of a voltage regulator provided by an embodiment of the present application.

FIG. 6 is a circuit principle diagram of a memory provided by an embodiment of the present application.

FIG. 7 is a timing schematic diagram of the memory shown in FIG. 6.

FIG. 8 is a flowchart schematic diagram of a voltage control method provided by an embodiment of the present application.

### DETAILED DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, not all of the embodiments. Based on the embodiments in the present application, all other embodiments obtained by those skilled in the art without creative efforts shall fall within the protection scope of the present application.

In addition, the terms “first” and “second” are used for descriptive purposes only and shall not be construed as indicating or implying relative importance or implicitly indicating the number of technical features specified, thereby features defined with “first” or “second” may explicitly or implicitly include one or more of such features, and in the description of the present invention, “multiple” means two or more unless explicitly and specifically limited otherwise.

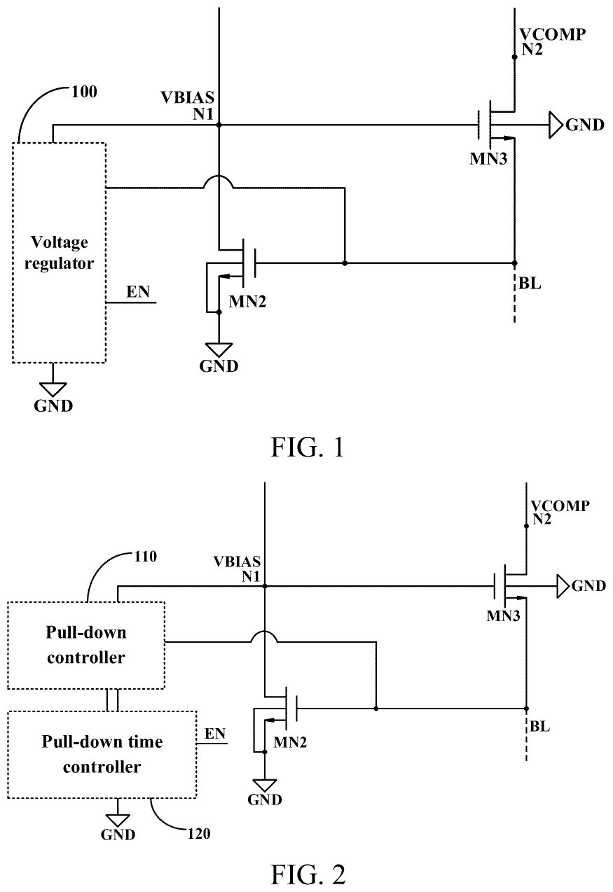

The embodiment provides a sense amplifier, please refer to FIG. 1 to FIG. 7, as shown in FIG. 1, the sense amplifier includes a first transistor MN3, a second transistor MN2, and a voltage regulator 100, the first transistor MN3 is configured to control connection between a second node N2 and a bit line BL based on the potential VBIAS of a first node N1; the second transistor MN2 is configured to pull down the potential VBIAS of the first node N1 based on the potential VBL of the bit line BL; the voltage regulator 100 is configured to pull down the potential VBIAS of the first node N1 based on an enable signal EN and the potential VBL of the bit line BL.

It can be understood that the sense amplifier provided by the present embodiment, through the voltage regulator 100 pulling down the potential VBIAS of the first node N1 based on the enable signal EN and the potential VBL of the bit line BL, can pull down the potential VBIAS of the first node N1 during the precharge phase, and further enable the potential VBL of the bit line BL to be reduced through the first transistor MN3, thereby alleviating the technical problem of the potential VBL of the bit line BL being excessively high during the precharge phase of a read operation.

It should be noted that the control terminal of the first transistor MN3 is connected to the first node N1, the first terminal of the first transistor MN3 is connected to the second node N2, and the second terminal of the first transistor MN3 is connected to the bit line BL. The control terminal of the second transistor MN2 is connected to the bit line BL, the first terminal of the second transistor MN2 is connected to the first node N1, and the second terminal of the second transistor MN2 is connected to a ground terminal GND. One end of the voltage regulator 100 is connected to the first node N1, the other end of the voltage regulator 100 is connected to the ground terminal GND, one control terminal of the voltage regulator 100 is connected to the bit line BL, and another control terminal of the voltage regulator 100 is connected to the enable signal EN.

The first transistor MN3 and the second transistor MN2 may exemplarily both be N-channel transistors, such as field-effect transistors. The first terminal is one of the source and the drain, and the second terminal is the other of the source and the drain. For example, when the first terminal is the source, the second terminal is the drain; or when the first terminal is the drain, the second terminal is the source. The control terminal may be the gate. In other embodiments, the first transistor MN3 and the second transistor MN2 may also both be bipolar junction transistors, the first terminal is one of the emitter and the collector, the second terminal is the other of the emitter and the collector. The control terminal is the base.

The first node N1 and the second node N2 may both be input terminals, and in some embodiments, they are current input terminals.

In one embodiment, as shown in FIG. 2, the voltage regulator 100 includes a pull-down time controller 120 and a pull-down controller 110, the pull-down time controller 120 is configured to control a pull-down time of the potential VBIAS of the first node N1 based on the enable signal EN. The pull-down controller 110 is configured to conduct a connection between the first node N1 and the pull-down time controller 120 when the potential VBL of the bit line BL is greater than a preset potential.

It should be noted that one end of the pull-down controller 110 is connected to the first node N1, the control terminal of the pull-down controller 110 is connected to the bit line BL, the other end of the pull-down controller 110 is connected to one end of the pull-down time controller 120, the other end of the pull-down time controller 120 is connected to the ground terminal GND, and the control terminal of the pull-down time controller 120 is connected to the enable signal EN. When the pull-down controller 110 and the pull-down time controller 120 are synchronously conducted, the first node N1 can discharge through the pull-down controller 110 and the pull-down time controller 120, thereby causing its own potential to decrease.

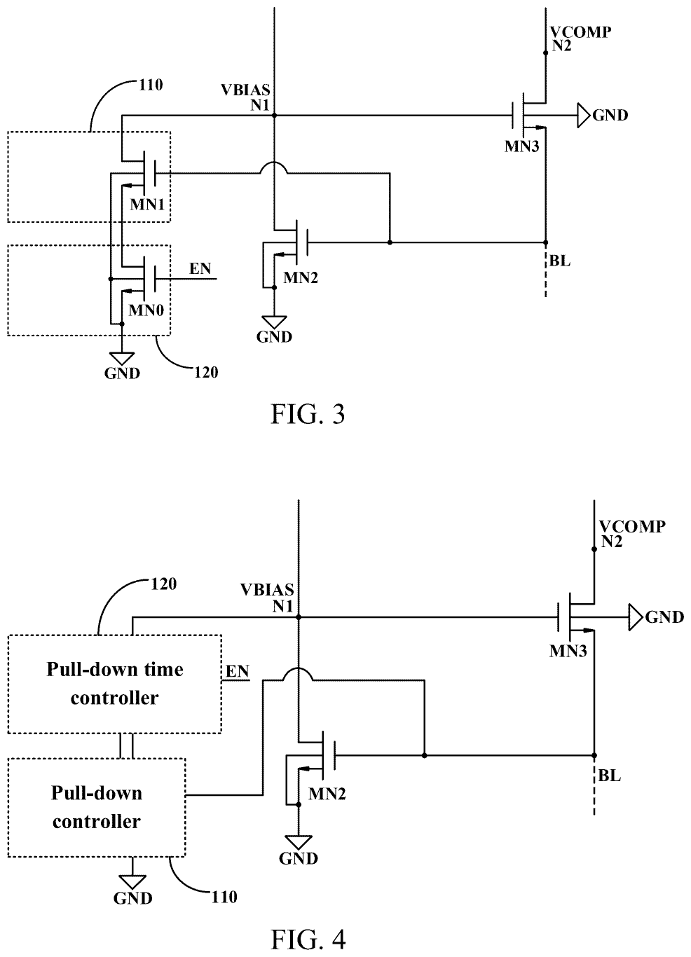

In one embodiment, as shown in FIG. 3, the pull-down controller 110 includes a third transistor MN1, a first terminal of the third transistor MN1 is connected to the first node N1, a control terminal of the third transistor MN1 is connected to the bit line BL, and a second terminal of the third transistor MN1 is connected to the pull-down time controller 120.

It should be noted that the third transistor MN1 may be an N-channel transistor, and the preset potential is a sum of a threshold voltage of the third transistor MN1 and a source potential of the third transistor MN1. When the potential VBL of the bit line BL exceeds the preset potential, it indicates that the potential VBL of the bit line BL is excessively high, which may lead to readout errors.

In one embodiment, as shown in FIG. 3, the pull-down time controller 120 includes a fourth transistor MN0, a first terminal of the fourth transistor MN0 is connected to the second terminal of the third transistor MN1, a control terminal of the fourth transistor MN0 is connected to the enable signal EN, and a second terminal of the fourth transistor MN0 is connected to the ground terminal GND.

It should be noted that the fourth transistor MN0 may be an N-channel transistor. When the potential VBL of the bit line BL exceeds the preset potential, the third transistor MN1 will be turned on, and at the same time, the enable signal EN will also control the fourth transistor MN0 to turn on, so that the first node N1 can discharge through the third transistor MN1 and the fourth transistor MN0, thereby reducing the potential VBIAS of the first node N1, reducing the conduction degree of the first transistor MN3 or turning off the first transistor MN3, thus preventing the potential VBL of the bit line BL from further increasing and/or causing the potential VBL of the bit line BL to decrease.

In one embodiment, as shown in FIG. 4, the voltage regulator 100 includes a pull-down time controller 120 and a pull-down controller 110, the pull-down time controller 120 is configured to control a pull-down time of the potential VBIAS of the first node N1 based on the enable signal EN. The pull-down controller 110 is configured to conduct a connection between the pull-down time controller 120 and the ground terminal GND when the potential VBL of the bit line BL is greater than a preset potential.

It should be noted that one end of the pull-down time controller 120 is connected to the first node N1, the control terminal of the pull-down time controller 120 is connected to the enable signal EN, and the other end of the pull-down time controller 120 is connected to one end of the pull-down controller 110. The control terminal of the pull-down controller 110 is connected to the bit line BL, and the other end of the pull-down controller 110 is connected to the ground terminal GND. When the pull-down controller 110 and the pull-down time controller 120 are synchronously conducted, the first node N1 can also discharge through the pull-down controller 110 and the pull-down time controller 120, thereby causing its own potential to decrease.

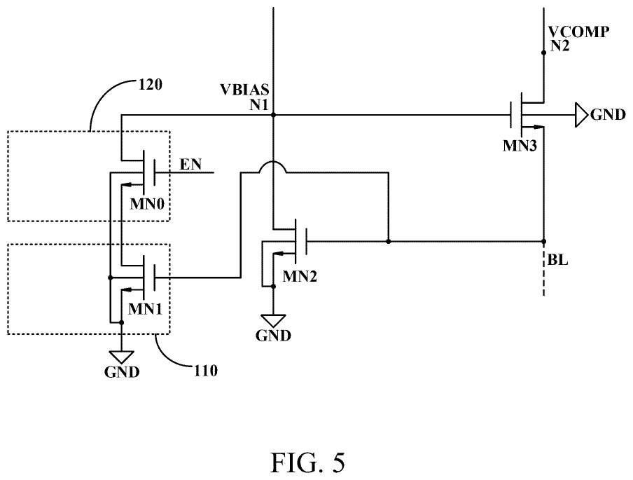

In one embodiment, as shown in FIG. 5, the pull-down controller 110 includes a third transistor MN1. A first terminal of the third transistor MN1 is connected to the pull-down time controller 120, a control terminal of the third transistor MN1 is connected to the bit line BL, and a second terminal of the third transistor MN1 is connected to the ground terminal GND.

It should be noted that the third transistor MN1 may be an N-channel transistor, and the preset potential is the threshold voltage of the third transistor MN1. When the potential VBL of the bit line BL exceeds the preset potential, it indicates that the potential VBL of the bit line BL is excessively high, which may lead to readout errors.

In one embodiment, as shown in FIG. 5, the pull-down time controller 120 includes a fourth transistor MN0, a first terminal of the fourth transistor MN0 is connected to the first node N1, a control terminal of the fourth transistor MN0 is connected to the enable signal EN, and a second terminal of the fourth transistor MN0 is connected to the first terminal of the third transistor MN1.

It should be noted that the fourth transistor MN0 may be an N-channel transistor. When the potential VBL of the bit line BL exceeds the preset potential, the third transistor MN1 will be turned on, and at the same time, the enable signal EN will also control the fourth transistor MN0 to turn on, so that the first node N1 can discharge through the third transistor MN1 and the fourth transistor MN0, thereby reducing the potential VBIAS of the first node N1, reducing the conduction degree of the first transistor MN3 or turning off the first transistor MN3, thus preventing the potential VBL of the bit line BL from further increasing and/or causing the potential VBL of the bit line BL to decrease.

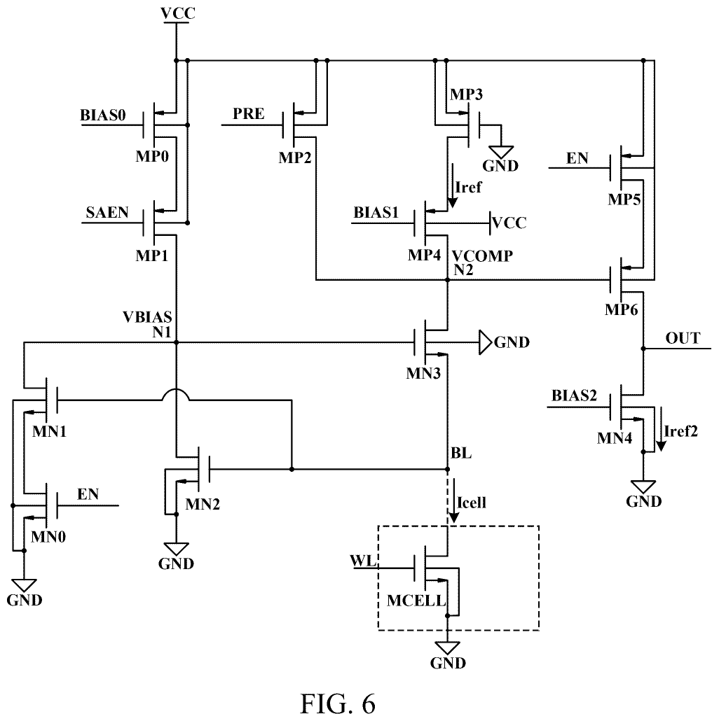

In one embodiment, as shown in FIG. 6, the sense amplifier further includes a fifth transistor MP5, a sixth transistor MP6, and a seventh transistor MN4, a first terminal of the fifth transistor MP5 is connected to a power supply terminal VCC, a control terminal of the fifth transistor MP5 is connected to a control terminal of the voltage regulator 100 to receive the enable signal EN; a first terminal of the sixth transistor MP6 is connected to a second terminal of the fifth transistor MP5, a control terminal of the sixth transistor MP6 is connected to the second node N2; a first terminal of the seventh transistor MN4 is connected to a second terminal of the sixth transistor MP6 and outputs a corresponding readout signal OUT, a control terminal of the seventh transistor MN4 is connected to a first bias signal BIAS2, and a second terminal of the seventh transistor MN4 is connected to the ground terminal GND.

It should be noted that the fifth transistor MP5 and the sixth transistor MP6 may both be P-channel transistors. The seventh transistor MN4 is an N-channel transistor. The fifth transistor MP5 and the fourth transistor MN0 may share the same enable signal EN, thereby reducing the number of signals required by the sense amplifier and also saving the number of transmission lines. The current flowing through the seventh transistor MN4 is denoted as Iref2.

In one embodiment, as shown in FIG. 6, the sense amplifier further includes an eighth transistor MP0 and a ninth transistor MP1, a first terminal of the eighth transistor MP0 is connected to the power supply terminal VCC, a control terminal of the eighth transistor MP0 is connected to a second bias signal BIAS0, a second terminal of the eighth transistor MP0 is connected to a first terminal of the ninth transistor MP1, a control terminal of the ninth transistor MP1 is connected to a first control signal SAEN, and a second terminal of the ninth transistor MP1 is connected to the first node N1.

It should be noted that the eighth transistor MP0 and the ninth transistor MP1 may exemplarily both be P-channel transistors. When both the eighth transistor MP0 and the ninth transistor MP1 are turned on, the first node N1 can be charged.

In one embodiment, as shown in FIG. 6, the sense amplifier further includes a tenth transistor MP2, a first terminal of the tenth transistor MP2 is connected to the power supply terminal VCC, a control terminal of the tenth transistor MP2 is connected to a precharge control signal PRE, and a second terminal of the tenth transistor MP2 is connected to the second node N2.

It should be noted that the tenth transistor MP2 may exemplarily be a P-channel transistor. When the tenth transistor MP2 is turned on, the second node N2 can be precharged.

In one embodiment, as shown in FIG. 6, the sense amplifier further includes an eleventh transistor MP3 and a twelfth transistor MP4. A first terminal of the eleventh transistor MP3 is connected to the power supply terminal VCC, a control terminal of the eleventh transistor MP3 is connected to the ground terminal GND, a second terminal of the eleventh transistor MP3 is connected to a first terminal of the twelfth transistor MP4, a control terminal of the twelfth transistor MP4 is connected to a third bias signal BIAS1, and a second terminal of the twelfth transistor MP4 is connected to the second node N2.

It should be noted that the eleventh transistor MP3 and the twelfth transistor MP4 may both be P-channel transistors. When the twelfth transistor MP4 is turned on, the second node N2 can be charged. The current flowing through the eleventh transistor MP3 and the twelfth transistor MP4 is denoted as Iref.

The potential VBIAS of the first node N1 represents the potential VBIAS of the first node N1. The potential VCOMP of the second node N2 represents the potential VCOMP of the second node N2. The substrate of each of the above-mentioned P-channel transistors is connected to the power supply terminal VCC, and the substrate of each of the above-mentioned N-channel transistors is connected to the ground terminal GND.

The above-mentioned bit line BL is also connected to one end of a memory cell MCELL in the memory, the other end of the memory cell MCELL is connected to the ground terminal GND, and the control terminal of the memory cell MCELL is connected to a word line WL. The current flowing through the memory cell MCELL is denoted as Icell.

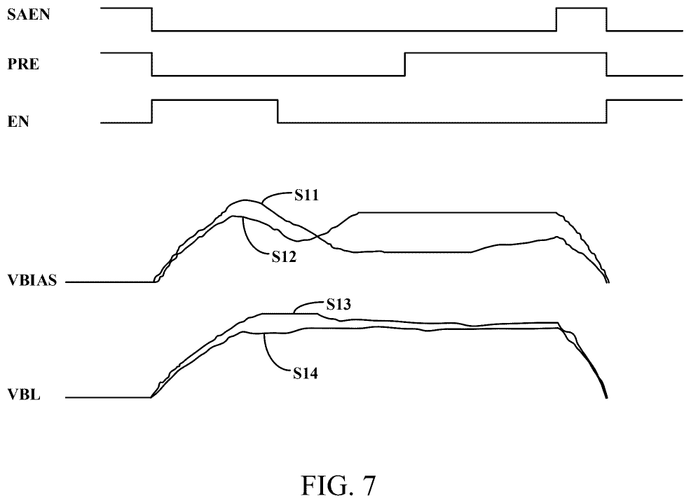

FIG. 7 is a timing schematic diagram of the memory shown in FIG. 6. It includes phases as follows:

First phase: The second bias signal BIAS0 provides a reference voltage to the gate of the eighth transistor MP0, and the ninth transistor MP1 serves as a switch transistor. When the precharge control signal PRE connected to the gate of the tenth transistor MP2 and the first control signal SAEN connected to the gate of the ninth transistor MP1 transition from a high potential of the power supply voltage to a low potential of “0”, since the gate potential of the second transistor MN2, i.e., the potential VBL of the bit line BL, is a low potential of “0”, the second transistor MN2 is in an off state, and the first node N1 is charged through the eighth transistor MP0 and the ninth transistor MP1; when the potential VBIAS of the first node N1 is higher than the threshold voltage of the first transistor MN3, the first transistor MN3 is turned on. The bit line BL is charged through the tenth transistor MP2 and the first transistor MN3; when the potential VBL of the bit line BL is higher than the threshold voltage of the second transistor MN2, the second transistor MN2 is turned on, which suppresses the continuous increase of the potential VBIAS of the first node N1, eventually reaching a balance, and both the potential VBIAS of the first node N1 and the potential VBL of the bit line BL will stabilize at a certain potential. The power supply voltage may be the potential of the power supply terminal VCC.

Second phase: After the potential VBL of the bit line BL and the potential VBIAS of the first node N1 stabilize, the potential VCOMP of the second node N2 is substantially close to the high potential of the power supply voltage. When the precharge control signal PRE connected to the gate of the tenth transistor MP2 transitions from a low potential of “0” to a high potential of the power supply voltage, the tenth transistor MP2 turns off, and the third bias signal BIAS1 provides a bias voltage to the gate of the twelfth transistor MP4, i.e., the twelfth transistor MP4 can provide a reference current Iref. Because the current Icell provided by memory cells MCELL with different threshold voltages will vary. When the current Icell is less than the reference current Iref, the potential VCOMP of the second node N2 basically remains stable at its original potential. When the current Icell is greater than the reference current Iref, the potential VCOMP of the second node N2 will decrease.

In the above-mentioned first phase, when the potential VBL of the bit line BL rises, the rise of the first node N1 is suppressed through the second transistor MN2, and the first node N1 will also suppress the rise of the potential VBL of the bit line BL through the first transistor MN3. However, the feedback requires time, and because the load of the potential VBL of the bit line BL varies (due to different positions of the memory cell MCELL, the potential of the bit line BL differs). The lighter the load of the potential VBL of the bit line BL, the more likely the potential VBL of the bit line BL is to overshoot excessively in the first phase, which will also cause the potential VBIAS of the first node N1 not to reach a stable potential after the first phase ends. Thus, in the second phase, if there is noise in the ground potential of the ground terminal GND and/or other noise, it will disrupt the state of the first phase, easily causing the sense amplifier to sense incorrectly. The third transistor MN1 and the fourth transistor MN0 divide the first phase into two time periods, namely a first time period and a second time period; in the first time period, the fourth transistor MN0 is turned on by the high potential of the enable signal EN, and through the turned-on third transistor MN1, the potential VBL of the bit line BL is first controlled at a lower potential; after the first time period ends, the sense amplifier basically reaches a stable state. In the second time period, the fourth transistor MN0 is turned off by the low potential of the enable signal EN, so that the potential VBL of the bit line BL and the potential VBIAS of the first node N1 ultimately reach the expected potential.

Third phase: The first bias signal BIAS2 provides a bias voltage to the gate of the seventh transistor MN4, i.e., the seventh transistor MN4 can provide a reference current Iref2. As the seventh transistor MN4 turns on, the potential of the readout signal OUT will decrease to a low potential of “0”. When the potential VCOMP of the second node N2 decreases to a certain value, the sixth transistor MP6 turns on; as the potential VCOMP of the second node N2 decreases and the fifth transistor MP5 turns on, the potential of the readout signal OUT will increase.

From this, it can be seen that through the sense amplifier, the memory cells MCELL with different threshold voltages can be distinguished. When the current Icell is greater than the current Iref, the readout signal OUT is a high potential of the power supply voltage. When the current Icell is less than the current Iref, the readout signal OUT remains a low potential of “0”.

In FIG. 7, curve S11 represents the change curve of the potential VBIAS of the first node N1 without using the voltage regulator 100. Curve S12 represents the change curve of the potential VBIAS of the first node N1 when using the voltage regulator 100. Curve S13 represents the change curve of the potential VBL of the bit line BL without using the voltage regulator 100. Curve S14 represents the change curve of the potential VBL of the bit line BL when using the voltage regulator 100. From this, it can be seen that when the enable signal EN is at a high potential, as the potential VBL of the bit line BL rises, the third transistor MN1 and the fourth transistor MN0 can pull down the potential VBIAS of the first node N1, thereby reducing the potential VBL of the bit line BL through the first transistor MN3.

In one embodiment, the present embodiment provides a memory, the memory includes the above-mentioned sense amplifier. The memory may be a memory chip, such as a Nor Flash chip, etc.

It can be understood that since the memory provided by the present embodiment includes the above-mentioned sense amplifier, it can also pull down the potential VBIAS of the first node N1 through the voltage regulator 100 based on the enable signal EN and the potential VBL of the bit line BL, pulling down the potential VBIAS of the first node N1 during the precharge phase, and further enabling the potential VBL of the bit line BL to be reduced through the first transistor MN3, thereby alleviating the technical problem of the potential VBL of the bit line BL being excessively high during the precharge phase of a read operation.

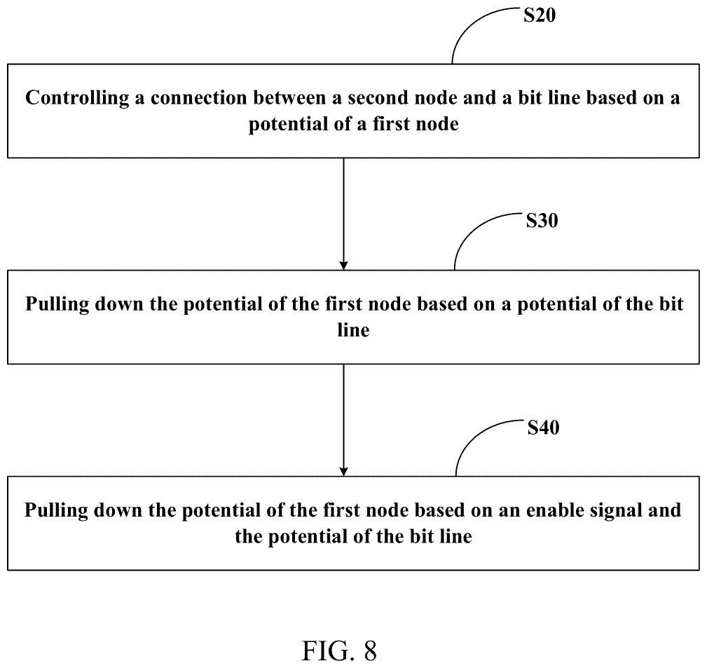

In one embodiment, the present embodiment provides a voltage control method, the voltage control method is applied to the above-mentioned sense amplifier, as shown in FIG. 8, and the voltage control method comprises steps as follows:

Step S20: Controlling a connection between a second node and a bit line based on a potential of a first node.

Step S30: Pulling down the potential of the first node based on a potential of the bit line.

Step S40: Pulling down the potential of the first node based on an enable signal and the potential of the bit line.

It can be understood that the voltage control method provided by the present embodiment, by pulling down the potential VBIAS of the first node N1 based on the enable signal EN and the potential VBL of the bit line BL, can pull down the potential VBIAS of the first node N1 during the precharge phase, and further enable the potential VBL of the bit line BL to be reduced through the potential VBIAS of the first node N1, thereby alleviating the technical problem of the potential VBL of the bit line BL being excessively high during the precharge phase of a read operation.

In one embodiment, the step of pulling down the potential VBIAS of the first node N1 based on the enable signal EN and the potential VBL of the bit line BL comprises: enabling the enable signal EN for a time period when the potential VBL of the bit line BL begins to change.

It should be noted that enabling the enable signal EN for a time period means: the enable signal EN can control the fourth transistor MN0 to turn on during the period, performing a pre-pull-down before the potential VBL of the bit line BL overshoots, effectively preventing the potential VBL of the bit line BL from overshooting. The enable signal EN controlling the fourth transistor MN0 to turn on may be a low potential or a high potential.

In one embodiment, the step of enabling the enable signal EN for a time period when the potential VBL of the bit line BL begins to change comprises: pulling down the potential VBIAS of the first node N1 based on the enable signal EN and the potential VBL of the bit line BL during a first time period when the potential VBL of the bit line BL begins to change; and stopping the pulling down of the potential VBIAS of the first node N1 based on the enable signal EN during a second time period following the first time period.

It should be noted that the first phase is divided into two time periods, namely a first time period and a second time period; in the first time period, the fourth transistor MN0 is turned on by the high potential of the enable signal EN, and through the turned-on third transistor MN1, the potential VBL of the bit line BL is first controlled at a lower potential; after the first time period ends, the sense amplifier basically reaches a stable state. In the second time period, the fourth transistor MN0 is turned off by the low potential of the enable signal EN, so that the potential VBL of the bit line BL and the potential VBIAS of the first node N1 ultimately reach the expected potential. Thus, even if the load of the potential VBL of the bit line BL is small, the potential VBL of the bit line BL will not be charged excessively high after the first phase ends, thereby allowing the potential VBIAS of the first node N1 to reach a stable potential after the first phase ends. Thus, in the second phase, even if there is noise in the ground potential of the ground terminal GND, it will not disrupt the stable state of the first phase, improving or avoiding the situation where the sense amplifier senses incorrectly.

In the above embodiments, the description of each embodiment has its own emphasis. For parts not detailed in a certain embodiment, reference may be made to the related descriptions of other embodiments.

The sense amplifier, voltage control method, and memory provided by the embodiments of the present application have been introduced in detail above; specific examples have been used herein to illustrate the principles and implementations of the present application, and the descriptions of the above embodiments are only configured to help understand the technical solutions and their core ideas of the present application; those skilled in the art should understand that they can still modify the technical solutions recorded in the foregoing embodiments or equivalently replace some of the technical features therein; and these modifications or replacements do not cause the essence of the corresponding technical solutions to depart from the scope of the technical solutions of the embodiments of the present application.

1. A sense amplifier, comprising:
a first transistor configured to control a connection between a second node and a bit line based on a potential of a first node;
a second transistor configured to pull down the potential of the first node based on a potential of the bit line; and
a voltage regulator configured to pull down the potential of the first node based on an enable signal and the potential of the bit line.

2. The sense amplifier according to claim 1, wherein the voltage regulator comprises:
a pull-down time controller configured to control a pull-down time of the potential of the first node based on the enable signal; and
a pull-down controller configured to conduct a connection between the first node and the pull-down time controller when the potential of the bit line is greater than a preset potential.

3. The sense amplifier according to claim 2, wherein the pull-down controller comprises a third transistor, a first terminal of the third transistor is connected to the first node, a control terminal of the third transistor is connected to the bit line, and a second terminal of the third transistor is connected to the pull-down time controller.

4. The sense amplifier according to claim 3, wherein the third transistor is an N-channel transistor, and the preset potential is a sum of a threshold voltage of the third transistor and a source potential of the third transistor.

5. The sense amplifier according to claim 3, wherein the pull-down time controller comprises a fourth transistor, a first terminal of the fourth transistor is connected to the second terminal of the third transistor, a control terminal of the fourth transistor is connected to the enable signal, and a second terminal of the fourth transistor is connected to a ground terminal.

6. The sense amplifier according to claim 1, wherein the voltage regulator comprises:
a pull-down time controller configured to control a pull-down time of the potential of the first node based on the enable signal; and
a pull-down controller configured to conduct a connection between the pull-down time controller and a ground terminal when the potential of the bit line is greater than a preset potential.

7. The sense amplifier according to claim 6, wherein the pull-down controller comprises a third transistor, a first terminal of the third transistor is connected to the pull-down time controller, a control terminal of the third transistor is connected to the bit line, and a second terminal of the third transistor is connected to the ground terminal.

8. The sense amplifier according to claim 7, wherein the pull-down time controller comprises a fourth transistor, a first terminal of the fourth transistor is connected to the first node, a control terminal of the fourth transistor is connected to the enable signal, and a second terminal of the fourth transistor is connected to the first terminal of the third transistor.

9. The sense amplifier according to claim 1, wherein the sense amplifier further comprises:
a fifth transistor, wherein a first terminal of the fifth transistor is connected to a power supply terminal, a control terminal of the fifth transistor is connected to a control terminal of the voltage regulator to receive the enable signal;
a sixth transistor, wherein a first terminal of the sixth transistor is connected to a second terminal of the fifth transistor, a control terminal of the sixth transistor is connected to the second node;
a seventh transistor, wherein a first terminal of the seventh transistor is connected to a second terminal of the sixth transistor and outputs a corresponding readout signal, a control terminal of the seventh transistor is connected to a first bias signal, and a second terminal of the seventh transistor is connected to a ground terminal.

10. The sense amplifier according to claim 1, wherein the sense amplifier further comprises:
a tenth transistor, wherein a first terminal of the tenth transistor is connected to a power supply terminal, a control terminal of the tenth transistor is connected to a precharge control signal, and a second terminal of the tenth transistor is connected to the second node;
an eleventh transistor, wherein a first terminal of the eleventh transistor is connected to the power supply terminal, and a control terminal of the eleventh transistor is connected to a ground terminal; and
a twelfth transistor, wherein a first terminal of the twelfth transistor is connected to a second terminal of the eleventh transistor, a control terminal of the twelfth transistor is connected to a third bias signal, and a second terminal of the twelfth transistor is connected to the second node.

11. The sense amplifier according to claim 1, wherein the enable signal is enabled for a time period when the potential of the bit line begins to change.

12. A voltage control method, comprising:
controlling a connection between a second node and a bit line based on a potential of a first node;
pulling down the potential of the first node based on a potential of the bit line; and
pulling down the potential of the first node based on an enable signal and the potential of the bit line.

13. The voltage control method according to claim 12, wherein the step of pulling down the potential of the first node based on an enable signal and the potential of the bit line comprises:
enabling the enable signal for a time period when the potential of the bit line begins to change.

14. The voltage control method according to claim 13, wherein step of enabling the enable signal for a time period when the potential of the bit line begins to change comprises:
pulling down the potential of the first node based on the enable signal and the potential of the bit line during a first time period when the potential of the bit line begins to change; and
stopping the pulling down of the potential of the first node based on the enable signal during a second time period following the first time period.

15. A memory, comprising a sense amplifier, wherein the sense amplifier comprises:
a first transistor configured to control a connection between a second node and a bit line based on a potential of a first node;
a second transistor configured to pull down the potential of the first node based on a potential of the bit line; and
a voltage regulator configured to pull down the potential of the first node based on an enable signal and the potential of the bit line.

16. The memory according to claim 15, wherein the voltage regulator comprises:
a pull-down time controller configured to control a pull-down time of the potential of the first node based on the enable signal; and
a pull-down controller configured to conduct a connection between the first node and the pull-down time controller when the potential of the bit line is greater than a preset potential.

17. The memory according to claim 16, wherein the pull-down controller comprises a third transistor, a first terminal of the third transistor is connected to the first node, a control terminal of the third transistor is connected to the bit line, and a second terminal of the third transistor is connected to the pull-down time controller.

18. The memory according to claim 17, wherein the third transistor is an N-channel transistor, and the preset potential is a sum of a threshold voltage of the third transistor and a source potential of the third transistor.

19. The memory according to claim 17, wherein the pull-down time controller comprises a fourth transistor, a first terminal of the fourth transistor is connected to the second terminal of the third transistor, a control terminal of the fourth transistor is connected to the enable signal, and a second terminal of the fourth transistor is connected to a ground terminal.

20. The memory according to claim 15, wherein the voltage regulator comprises:
a pull-down time controller configured to control a pull-down time of the potential of the first node based on the enable signal; and
a pull-down controller configured to conduct a connection between the pull-down time controller and a ground terminal when the potential of the bit line is greater than a preset potential.
